(19) United States
(12) Patent Application Publication
(10) Pub. No.: US 2026/0123453 A1
(43) Pub. Date: Apr. 30, 2026

(54) SEMICONDUCTOR PACKAGES WITH DISTANCED CONDUCTIVE TERMINALS

(71) Applicant: TEXAS INSTRUMENTS INCORPORATED, Dallas, TX (US)

(72) Inventors: Rongwei ZHANG, Plano, TX (US); Enis TUNCER, Dallas, TX (US)

(21) Appl. No.: 18/934,051

(22) Filed: Oct. 31, 2024

(51) Int. Cl. H01L 23/495; H01L 21/48; H01L 23/00; H01L 23/31

(52) U.S. Cl. CPC H10W 70/421; H10W 74/114; H10W 70/048; H10W 70/457; H10W 72/073; H10W 72/075; H10W 72/07502; H10W 72/884; H10W 90/736; H10W 90/756

(57) ABSTRACT

In examples, a semiconductor package includes a semiconductor die having a device side in which circuitry is formed and a non-device side opposite the device side. The package includes a die attach film contacting the non-device side of the semiconductor die; a first conductive terminal contacting the die attach film, the semiconductor die cantilevered by the first conductive terminal; a second conductive terminal separated from the die attach film, the first and second conductive terminals configured to operate in different voltage domains; bond wires coupling the device side of the semiconductor die to the first and second conductive terminals; and a mold compound contacting the semiconductor die, the die attach film, the first and second conductive terminals, and the bond wires, the mold compound present in between the die attach film and the second conductive terminal, each of the first and second conductive terminals exposed from at least one lateral surface of the mold compound.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique, such as by wire bonding.

### SUMMARY

In examples, a semiconductor package includes a semiconductor die having a device side in which circuitry is formed and a non-device side opposite the device side. The package includes a die attach film contacting the non-device side of the semiconductor die; a first conductive terminal contacting the die attach film, the semiconductor die cantilevered by the first conductive terminal; a second conductive terminal separated from the die attach film, the first and second conductive terminals configured to operate in different voltage domains; bond wires coupling the device side of the semiconductor die to the first and second conductive terminals; and a mold compound contacting the semiconductor die, the die attach film, the first and second conductive terminals, and the bond wires, the mold compound present in between the die attach film and the second conductive terminal, each of the first and second conductive terminals exposed from at least one lateral surface of the mold compound.

In examples, a method for manufacturing a semiconductor package includes coupling a die attach film to a non-device side of a semiconductor die, the semiconductor die including a device side opposite the non-device side, the device side having circuitry formed therein; contacting the die attach film to one or more conductive terminals of a lead frame, the one or more conductive terminals adequately sized to mechanically support the semiconductor die and the die attach film, the lead frame including a conductive terminal separated from the die attach film by a distance ranging from 10 microns to 1000 microns; coupling bond wires to the device side of the semiconductor die, the one or more conductive terminals, and the conductive terminal; covering the semiconductor die, the die attach film, and the lead frame with a mold compound, the mold compound positioned between the conductive terminal and the die attach film; and sawing the mold compound to produce the semiconductor package, wherein, after the sawing, the conductive terminal and each of the one or more conductive terminals is exposed from at least one lateral surface of the mold compound, the conductive terminal configured to operate in a different voltage domain than the one or more conductive terminals.

### BRIEF DESCRIPTION OF THE DRAWINGS

FIGS. 1A, 1B, 1C, 1D, 1E, and 1F are perspective, top-down, bottom-up, profile, profile, and cross-sectional views of a semiconductor package including distanced conductive terminals, in accordance with various examples.

FIGS. 2A, 2B, 2C, 2D, 2E, and 2F are perspective, top-down, bottom-up, profile, profile, and cross-sectional views of a semiconductor package including distanced conductive terminals, in accordance with various examples.

FIGS. 3A, 3B, 3C, 3D, 3E, and 3F are perspective, top-down, bottom-up, profile, profile, and cross-sectional views of a semiconductor package including distanced conductive terminals, in accordance with various examples.

FIG. 4 is a flow diagram of a method for manufacturing a semiconductor package including distanced conductive terminals, in accordance with various examples.

FIGS. 5A, 5B, 5C, 6A, 6B, 7A, 7B, 8A, 8B, 9A, and 9B are a process flow depicting the manufacture of a semiconductor package including distanced conductive terminals, in accordance with various examples.

FIGS. 10A and 10B are top-down and perspective views of a portion of a process flow depicting the manufacture of a semiconductor package including distanced conductive terminals, in accordance with various examples.

FIG. 11 is a block diagram of an electronic device including a semiconductor package having distanced conductive terminals, in accordance with various examples.

### DETAILED DESCRIPTION

Semiconductor packages may have varying configurations. In some semiconductor packages, a die attach film is coupled to the backside of a semiconductor die. The die attach film is used to couple the semiconductor die to a set of conductive terminals, or leads. Bond wires are coupled to the semiconductor die and to the conductive terminals. A mold compound is then applied to cover the various structures of the package.

The conductive terminals may operate in differing voltage domains. For example, a first set of conductive terminals may be configured to carry substantially higher positive voltages than a second set of conductive terminals. Because the high-voltage conductive terminals operate at higher voltages than the semiconductor material of the semiconductor die, the high-voltage conductive terminals may be considered as anodes relative to the semiconductor die, and the semiconductor die may be considered as a cathode relative to the high-voltage conductive terminals. Conductive terminals generally include metals such as copper and silver, the ions of which are susceptible to electrochemical migration (ECM) from anode to cathode. Thus, the metal ions of the high-voltage conductive terminals may migrate toward the semiconductor die, resulting in the formation of conductive dendrites in the die attach film that is between the high-voltage conductive terminals and the semiconductor die. These dendrites operate as an electrical pathway between the semiconductor die and the high-voltage conductive terminals, compromising the functional integrity of the semiconductor package.

Furthermore, semiconductor wafers are frequently singulated by mechanical saws to produce the aforementioned semiconductor dies. Mechanical sawing can result in “chipping” of a semiconductor die, which is the formation of semiconductor debris on or near the lateral surfaces of the semiconductor die. Such chips can physically couple the semiconductor die to any of the conductive terminals, thereby creating an electrical pathway between the semiconductor die and the conductive terminal(s). Such electrical pathways compromise the functional integrity of the semiconductor package, irrespective of whether the chips couple the semiconductor die to high-voltage conductive terminals or low-voltage conductive terminals.

This disclosure describes various examples of a semiconductor package that mitigates the technical challenges described above by distancing one or more of the conductive terminals from the die attach film, where dendrites commonly form. Mold compound is present in between the conductive terminal and the die attach film. The thickness of the mold compound between the conductive terminal and the die attach film ranges between 10 microns and 1000 microns for an operating voltage range of 1 V to 8000 V, and is adequate to avoid dielectric breakdown when subjected to the range of voltages over which the semiconductor package is configured to operate. Because mold compound has a high breakdown voltage, particularly at the thicknesses described above, the risk of dielectric breakdown and ECM between the conductive terminal and the die attach film is mitigated. Furthermore, the distance between the conductive terminal and the semiconductor die is adequate to prevent semiconductor die chips from physically coupling the semiconductor die or die attach film to the conductive terminal, thus mitigating the risk of chipping.

In examples, a semiconductor package comprises a semiconductor die having a device side in which circuitry is formed and a non-device side opposite the device side. The semiconductor package includes a die attach film contacting the non-device side of the semiconductor die. The semiconductor package includes a first conductive terminal contacting the die attach film, and a second conductive terminal separated from the die attach film. The first and second conductive terminals are configured to operate in different voltage domains. The semiconductor package includes bond wires coupling the device side of the semiconductor die to the first and second conductive terminals. The semiconductor package includes a mold compound contacting the semiconductor die, the die attach film, the first and second conductive terminals, and the bond wires. The mold compound is present in between the die attach film and the second conductive terminal. Each of the first and second conductive terminals is exposed from one or more surfaces (e.g., lateral and/or bottom surfaces) of the mold compound.

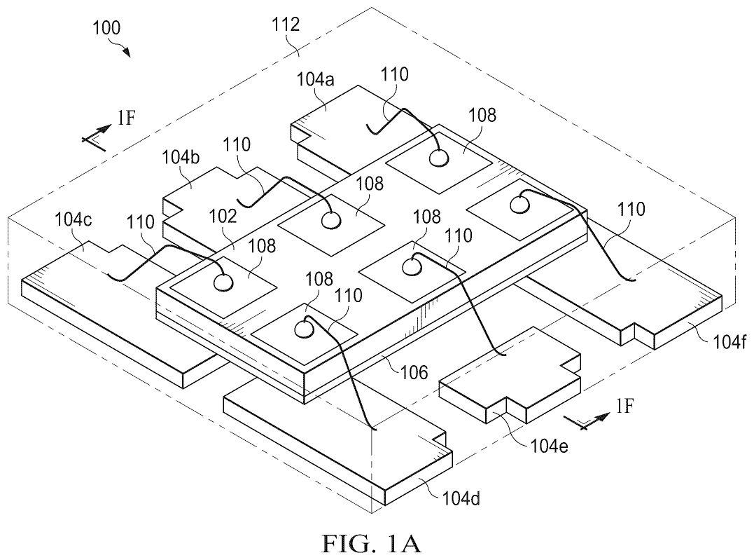

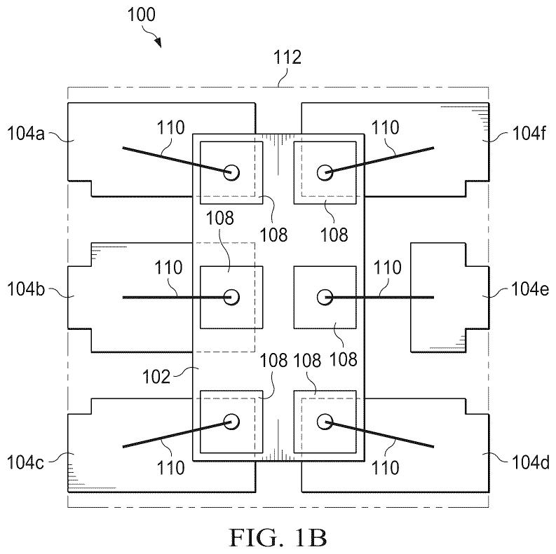

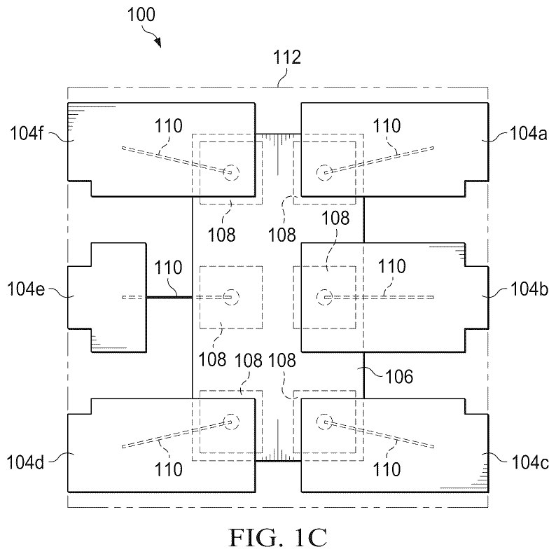

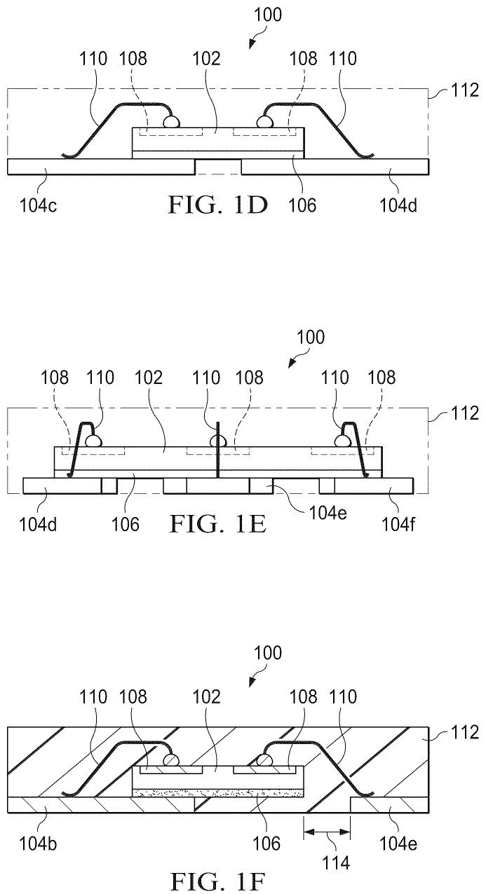

FIGS. 1A-1F are perspective, top-down, bottom-up, profile, profile, and cross-sectional views of a semiconductor package including distanced conductive terminals, in accordance with various examples. More particularly, FIGS. 1A-1F depict a semiconductor package 100 having a semiconductor die 102 coupled to a set of conductive terminals 104a-104f (which may be collectively referred to herein as conductive terminals 104) by way of a die attach film 106. The conductive terminals may include copper and may be plated with silver. The semiconductor die 102 includes a set of bond pads 108. Each of the bond pads 108 is coupled to a respective conductive terminal 104a-104f by way of a bond wire 110. A mold compound 112 physically contacts and covers the various structures of the semiconductor package 100. The distal ends of the conductive terminals 104 may be exposed to exterior surface(s) of the mold compound 112.

The conductive terminals 104 may be useful to the semiconductor package 100 in one or more ways. For example, the conductive terminals 104 may provide mechanical support for the semiconductor die 102, such as by supporting the weight of the semiconductor die 102. Furthermore, the conductive terminals 104 may provide an electrical pathway between the bond wires 110 and electronic components outside of the semiconductor package 100 to which the semiconductor package 100 is coupled, such as a printed circuit board (PCB). In some examples, one or more of the conductive terminals 104 provides mechanical support. In some examples, one or more of the conductive terminals 104 provides an electrical pathway. In some examples, one or more of the conductive terminals 104 provides both mechanical support and an electrical pathway. In some examples, one or more of the conductive terminals 104 provides neither mechanical support nor an electrical pathway.

One or more of the conductive terminals 104 may belong to a different voltage domain than another one or more of the conductive terminals 104. For example, the conductive terminals 104b and 104e may belong to, and be configured to operate in, separate voltage domains, with the conductive terminal 104b configured to operate in a lower voltage domain and the conductive terminal 104e configured to operate in a higher voltage domain. Because the conductive terminal 104e is configured to operate in a higher voltage domain, during operation, the conductive terminal 104e may operate as an anode relative to the semiconductor die 102, which may operate as a cathode. Consequently, dendrites could form in the die attach film 106, thereby establishing an electrical pathway between the conductive terminal 104e and the semiconductor die 102. To prevent such dendrite formation, the conductive terminal 104e is distanced from the die attach film 106 and the semiconductor die 102 in the horizontal direction. Although this distancing is visible in multiple views, the cross-sectional view of FIG. 1F shows this distancing particularly clearly. FIG. 1F denotes a distance 114 between the conductive terminal 104e, which in this example is in a high-voltage domain, and the die attach film 106 (and the semiconductor die 102), which are not in the high-voltage domain. This distance 114 precludes dendrite formation. Furthermore, the distance 114 precludes any chips (e.g., debris formed during wafer singulation and that may still be attached to the semiconductor die 102) that may be attached to or in the proximity of the semiconductor die 102 from coupling to the conductive terminal 104e, which would form an electrical pathway therebetween. Thus, the distance 114 should be large enough to prevent such chips from forming such an electrical pathway. The distance 114 ranges between 10 microns and 1000 microns for a voltage operating range of 1 V to 8000 V, with a distance above this range being disadvantageous because it results in an unnecessarily large and bulky semiconductor package 100, and with a distance below this range being disadvantageous because it unacceptably raises the risk of dendrite formation and/or a chip forming an electrical pathway between the semiconductor die 102 and the conductive terminal 104e. The distance 114 is adequate to avoid dielectric breakdown when the mold compound 112 in the distance 114 is subjected to the range of voltages over which the circuitry of the semiconductor die 102 is configured to operate. The distance 114 is not restricted to any particular conductive terminal 104.

A bond wire 110 may couple the conductive terminal 104e to a device side of the semiconductor die 102 in which circuitry is formed, and specifically, to a bond pad on the device side of the semiconductor die 102. Such connections are useful, as they are intentionally formed and facilitate proper operation of the semiconductor package 100. In contrast, the aforementioned dendrite formation between the conductive terminal 104e and the body of the semiconductor die 102 (e.g., the non-device side of the semiconductor die 102 opposite the device side of the semiconductor die 102) is undesirable and disadvantageous, and thus the distance 114 precludes such dendrite formation.

Although the example of FIG. 1F assumes that the conductive terminal 104e that is distanced from the die attach film 106 and the semiconductor die 102 operates as an anode and the semiconductor die 102 operates as a cathode, in examples, the conductive terminal 104e may be configured to operate in a low voltage domain, and thus the conductive terminal 104e may operate as a cathode and the semiconductor die 102 may operate as an anode. Regardless of the particular configuration of anode and cathode or high-voltage domain and low-voltage domain, the distancing of conductive terminals (e.g., conductive terminal 104e) may be useful to prevent dendrite formation and to prevent the formation of electrical pathways by chips.

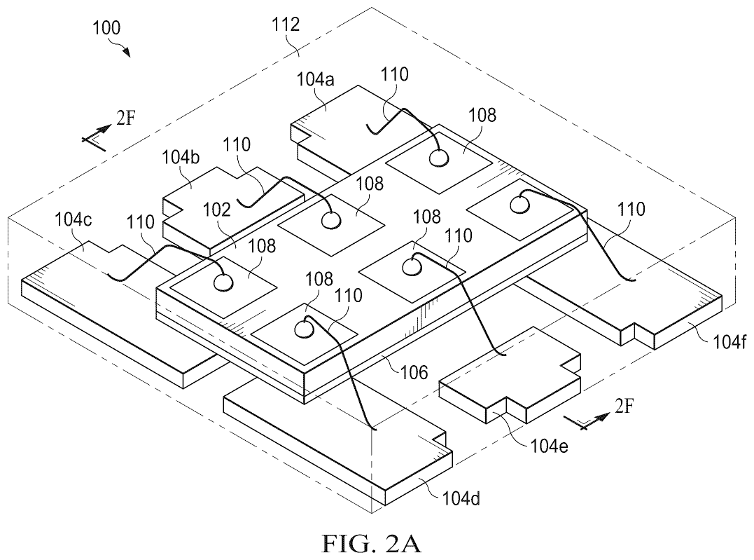

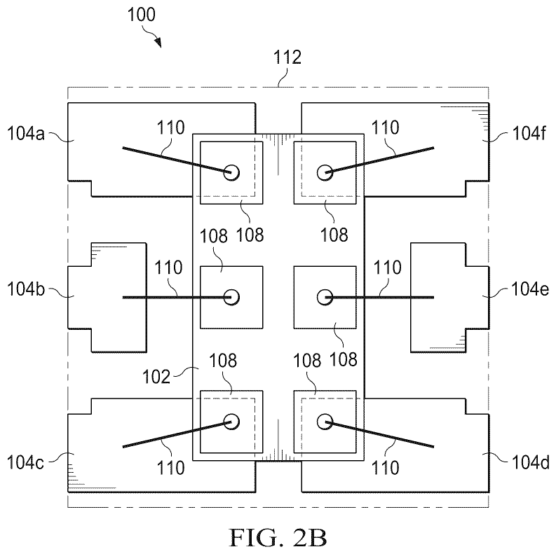

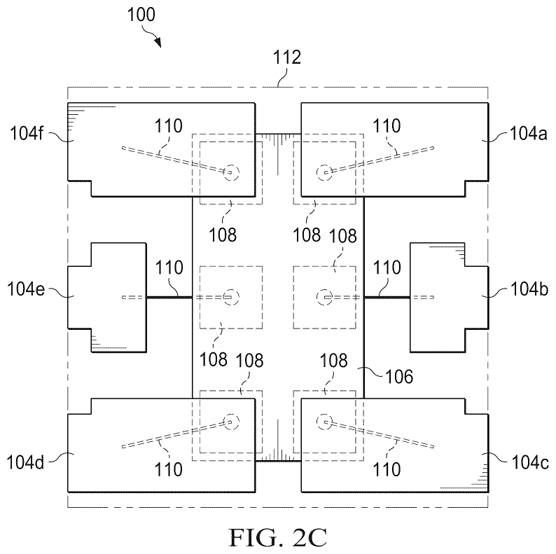

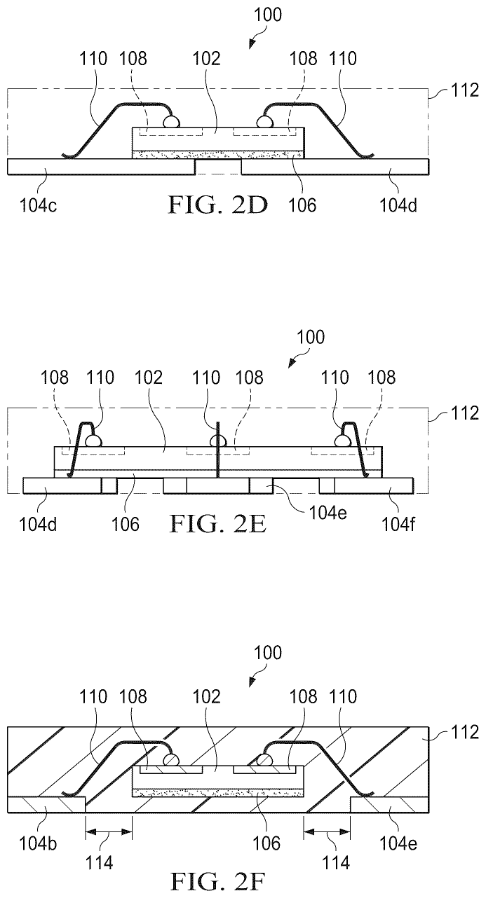

In some examples, multiple conductive terminals 104 may be distanced from the die attach film 106 and the semiconductor die 102. For example, multiple conductive terminals 104 may operate in a different voltage domain than the semiconductor die 102, such as in a high voltage domain, and thus dendrite formation, or the formation of electrical pathways by chips, is a risk. To prevent dendrite formation and shorting caused by chips, multiple conductive terminals are distanced from the die attach film 106 and the semiconductor die 102. FIGS. 2A-2F are perspective, top-down, bottom-up, profile, profile, and cross-sectional views of the semiconductor package 100 of FIGS. 1A-1F, except that the conductive terminals 104b and 104e are both distanced from the die attach film 106 and the semiconductor die 102. The distance between each of the conductive terminals 104b, 104e and the die attach film 106 in the horizontal direction is the same as the range stated above, with the same attendant risks of deviating outside of the range as described above.

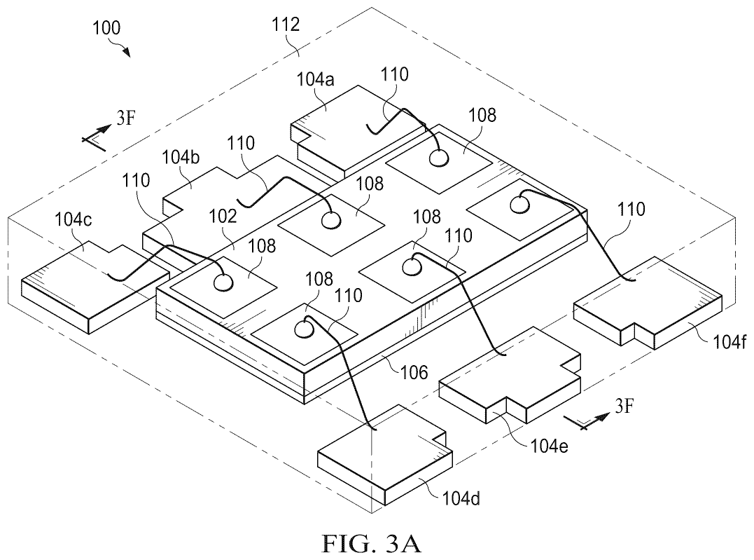

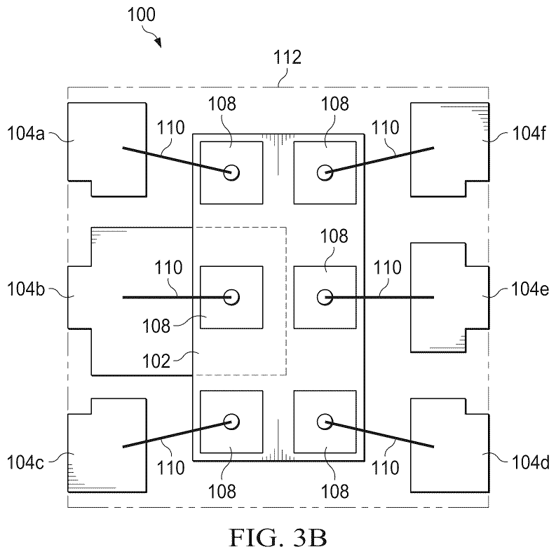

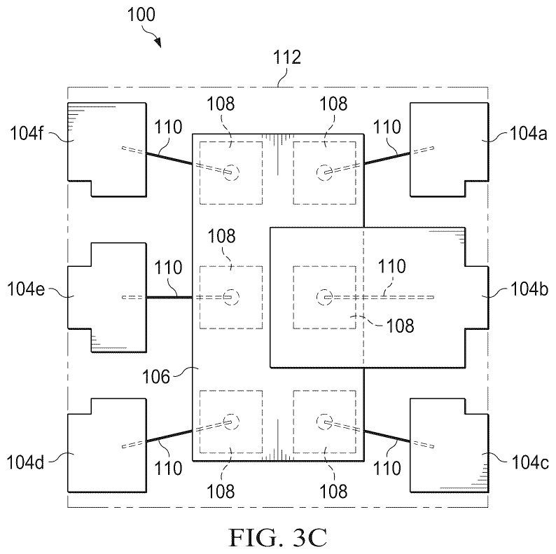

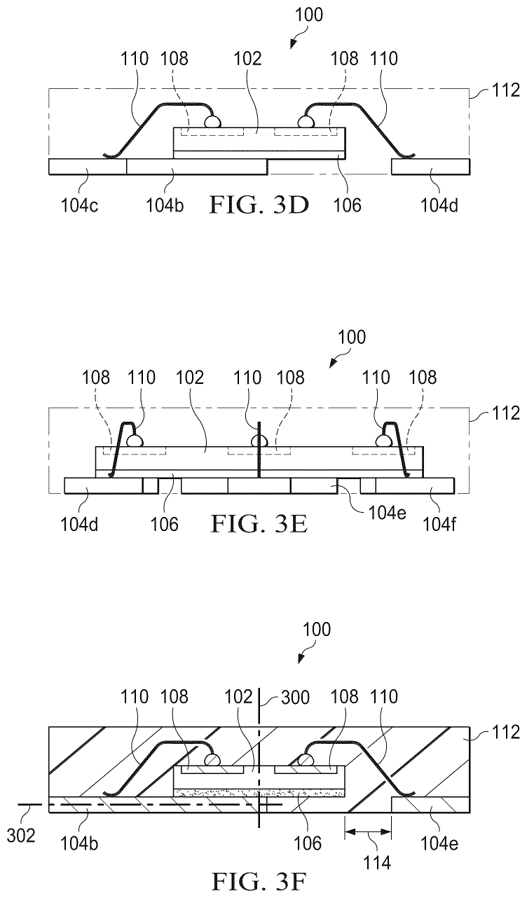

When one or more conductive terminals 104 is distanced from the die attach film 106 and the semiconductor die 102, the semiconductor die 102 lacks mechanical support from that conductive terminal 104. For example, referring to FIG. 2A, because both the conductive terminals 104b, 104e are distanced from the die attach film 106 and the semiconductor die 102, the conductive terminals 104b, 104e do not mechanically support the semiconductor die 102. Rather, the remaining conductive terminals 104a, 104c, 104d, and 104f mechanically support the semiconductor die 102. Accordingly, the semiconductor package 100 should be designed and manufactured to ensure that the semiconductor die 102 receives adequate mechanical support from whichever conductive terminals 104 provide such support. FIGS. 3A-3F are perspective, top-down, bottom-up, profile, profile, and cross-sectional views of the semiconductor package 100 of FIGS. 1A-1F, except that in FIGS. 3A-3F, the conductive terminals 104a and 104c-104f are distanced from the die attach film 106 and the semiconductor die 102, and the conductive terminal 104b is not distanced from the die attach film 106 and the semiconductor die 102. Accordingly, in this example, only the conductive terminal 104b provides mechanical support to the semiconductor die 102. Thus, the conductive terminal 104b should be shaped and sized to ensure adequate mechanical support for the semiconductor die 102. As FIGS. 3A-3F show, the conductive terminal 104b is wider than the remaining conductive terminals 104, and the conductive terminal 104b is also longer than the remaining conductive terminals 104. For instance, as FIG. 3F shows, the conductive terminal 104b has a length that extends past the midline 300 of the semiconductor die 102 as measured along the axis 302 of the conductive terminal 104b. Stated another way, the conductive terminal 104b contacts more than half of a width of the die attach film 106 as measured along the axis 302 of the conductive terminal 104b. As the top-down view of FIG. 3B shows, the conductive terminal 104b may be sufficiently wide that the conductive terminal 104b contacts the middle one-third of the length of the die attach film 106. In this way, the conductive terminal 104b supports the semiconductor die 102 and the die attach film 106 even though the remaining conductive terminals 104a and 104c-104f are distanced from the semiconductor die 102 and the die attach film 106.

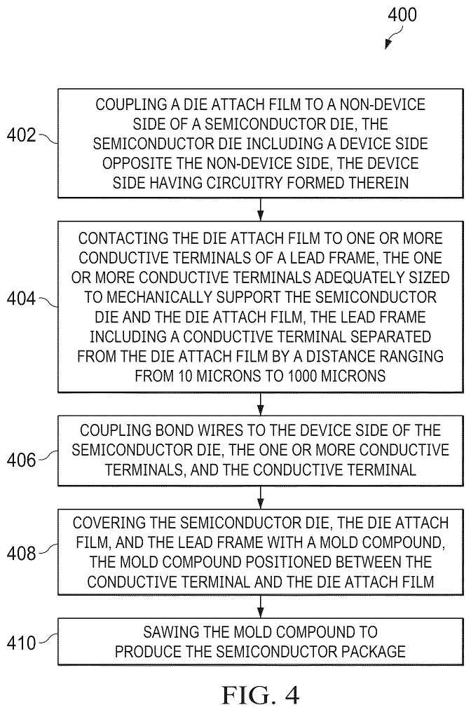

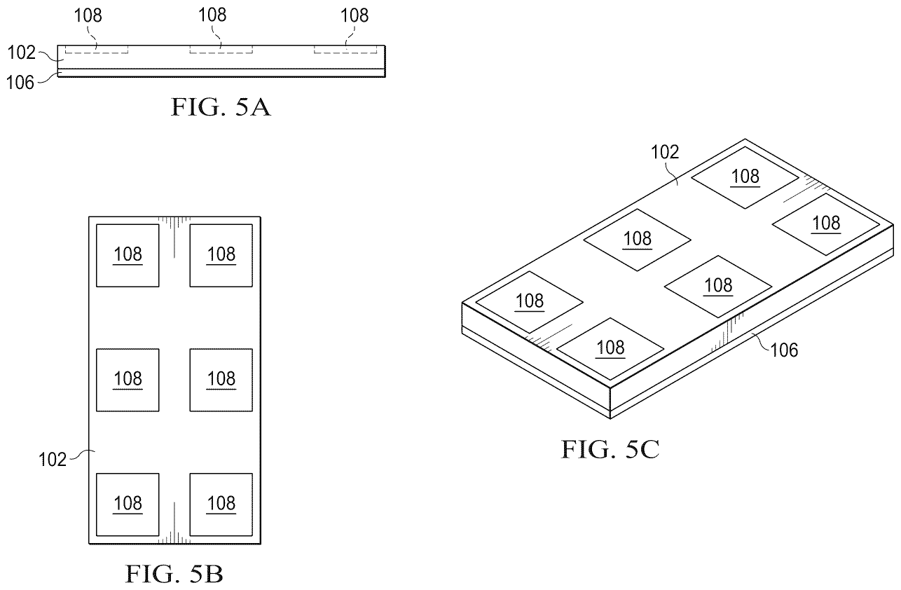

FIG. 4 is a flow diagram of a method 400 for manufacturing a semiconductor package including distanced conductive terminals, in accordance with various examples. FIGS. 5A-9B are a process flow depicting the manufacture of a semiconductor package including distanced conductive terminals, in accordance with various examples. Accordingly, FIGS. 4 and 5A-9B are described in parallel with each other.

The method 400 may include coupling a die attach film to a non-device side of a semiconductor die, with the semiconductor die including a device side opposite the non-device side, and the device side having circuitry formed therein (402). FIG. 5A is a cross-sectional view of the semiconductor die 102 coupled to the die attach film 106. The top side of the semiconductor die 102 is the device side having circuitry formed therein, and the bottom side of the semiconductor die 102 is the non-device side. The die attach film 106 is coupled to the non-device side of the semiconductor die 102. FIG. 5B is a top-down view of the structure of FIG. 5A. FIG. 5C is a perspective view of the structure of FIG. 5A.

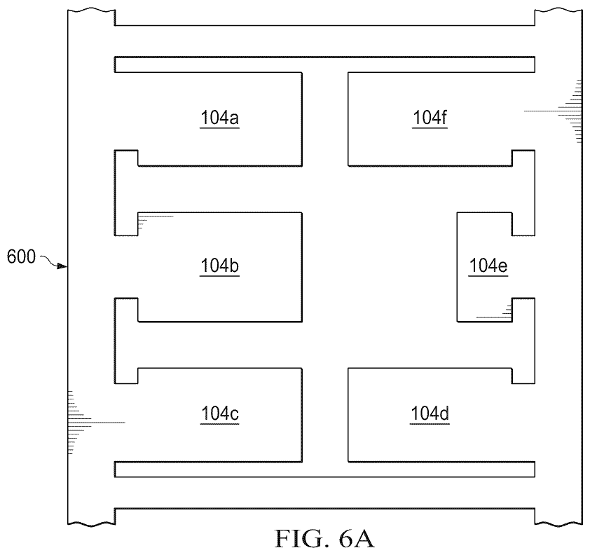

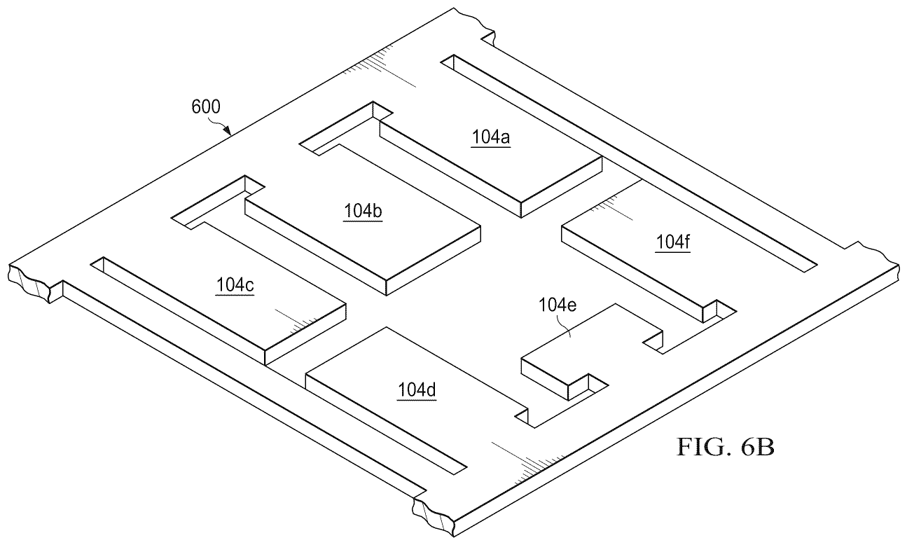

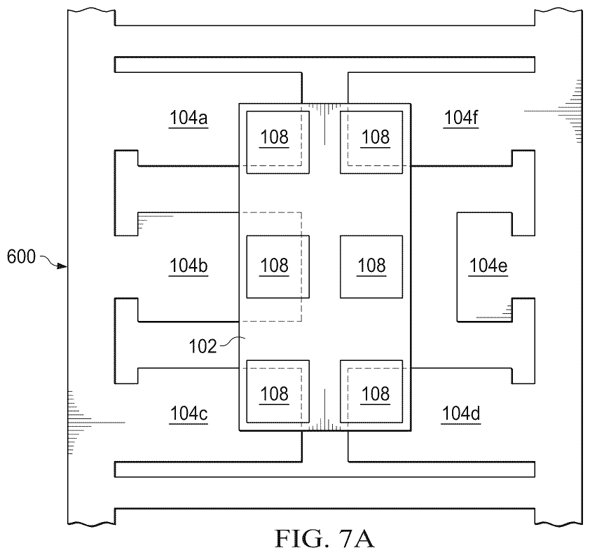

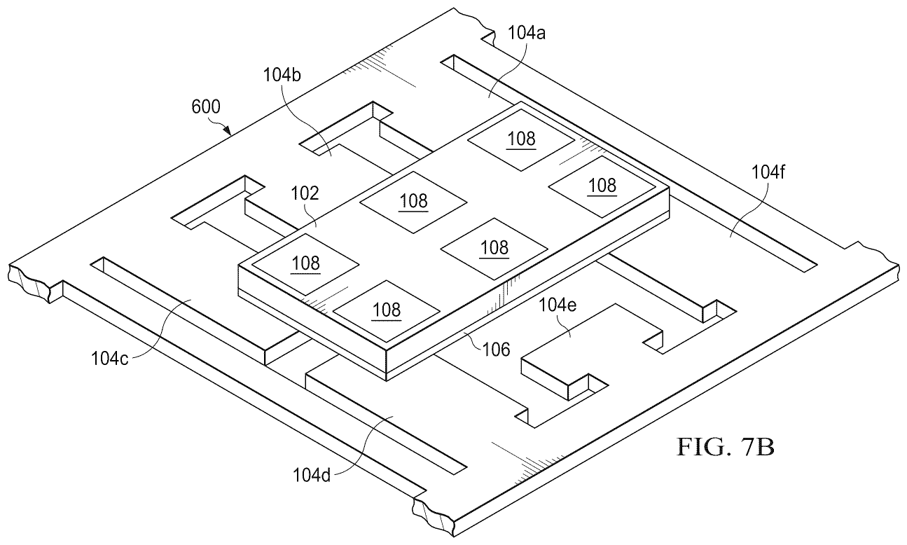

The method 400 may include contacting the die attach film to one or more conductive terminals of a lead frame (404). The one or more conductive terminals is adequately sized to mechanically support the semiconductor die and the die attach film (404). The lead frame includes a conductive terminal separated from the die attach film by a distance ranging from 10 microns to 1000 microns (404). FIG. 6A is a top-down view of a lead frame 600 having the conductive terminals 104. As shown, the conductive terminal 104e is shorter than the remaining conductive terminals 104, because the conductive terminal 104e is to be distanced from the die attach film 106 and the semiconductor die 102. FIG. 6B is a perspective view of the structure of FIG. 6A. FIG. 7A is a top-down view of the structure of FIG. 6A, except that the semiconductor die 102 and die attach film 106 of FIGS. 5A-5C have been coupled to the lead frame 600, and specifically, to the conductive terminals 104a-d and 104f. The conductive terminal 104e is distanced from the die attach film 106 and the semiconductor die 102 by the distance range described above. FIG. 7B is a perspective view of the structure of FIG. 7A.

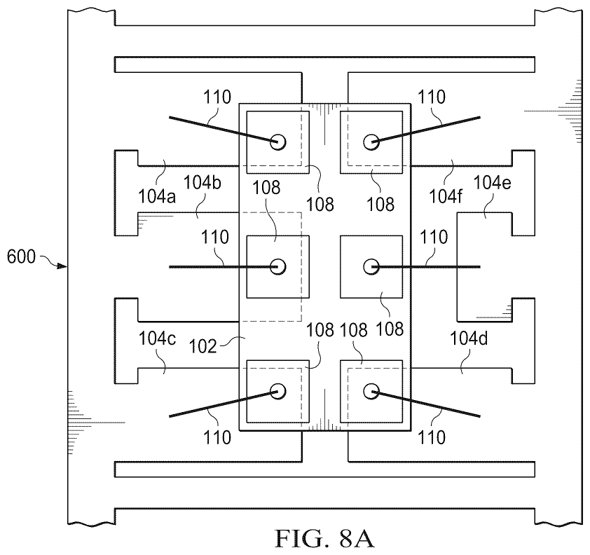

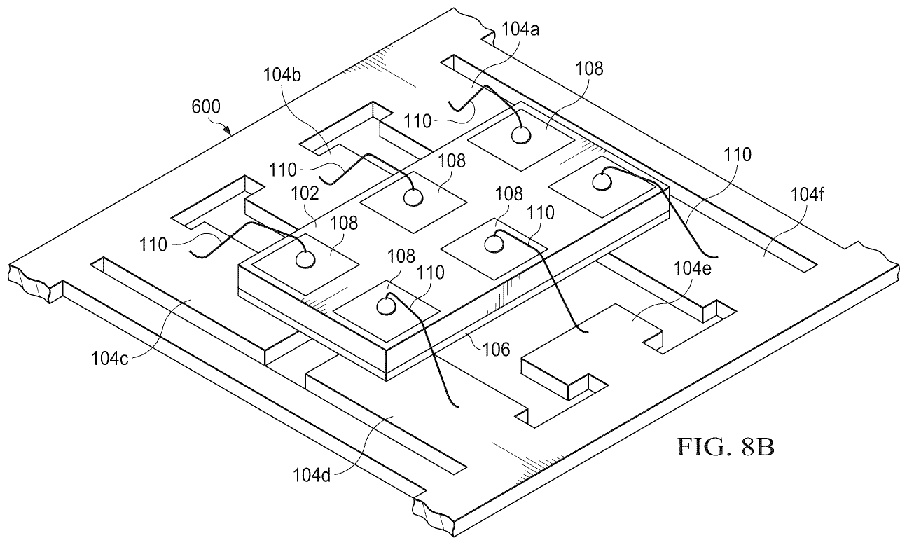

The method 400 may include coupling bond wires to the device side of the semiconductor die, the one or more conductive terminals, and the distanced conductive terminal (406). FIG. 8A is a top-down view of the structure of FIG. 7A, except that bond wires 110 couple the bond pads 108 of the semiconductor die 102 to the conductive terminals 104a-104f. Any suitable wire bonding technique may be used, such as ball bonds, stitch bonds, etc. FIG. 8B is a perspective view of the structure of FIG. 8A.

The die attach film 106 should be sufficiently rigid so as to provide adequate support to the semiconductor die 102 during wire bonding. The rigidity of the die attach film 106 should be at least 50 MPa at the wire bonding temperatures for copper wires, with a rigidity below this range being disadvantageous because the die attach film will be too pliable, resulting in inadequate wire bond strength. Examples of the die attach film 106 include epoxy and acrylate based materials, such as commercial ATB-F125.

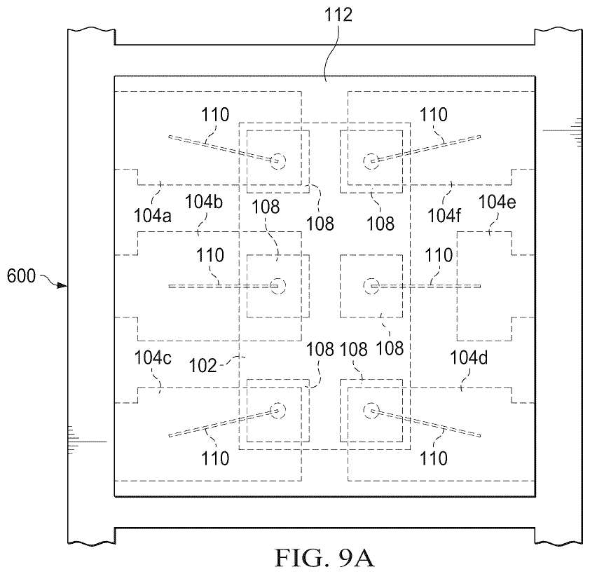

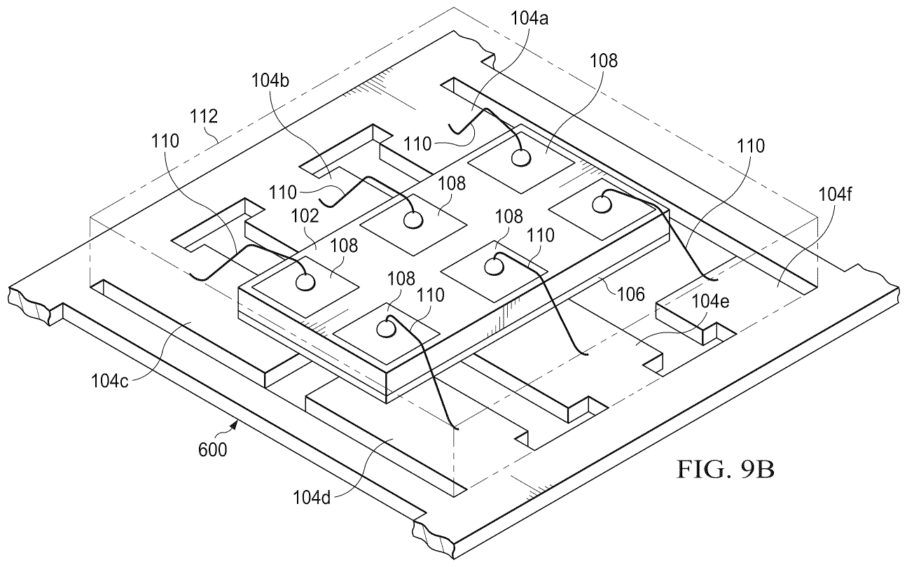

The method 400 may include covering the semiconductor die, the die attach film, and the lead frame with a mold compound, where the mold compound is positioned between the conductive terminal and the die attach film (408). FIG. 9A is a top-down view of the structure of FIG. 8A, except that the mold compound 112 has been applied to physically contact and cover the various structures of the semiconductor package 100. FIG. 9B is a perspective view of the structure of FIG. 9A. Where a conductive terminal 104 is distanced from the die attach film 106, the mold compound 112 is present therebetween, meaning, in that distance. For example, in FIG. 1F, the mold compound 112 is present in the distance 114. The presence of the mold compound 112 in this distance 114 discourages dendrite formation. Such distances, such as the distance 114, may be referred to as a thickness of the mold compound 112 in this location.

The method 400 may include sawing the mold compound to produce an individual semiconductor package (410), such as the semiconductor package 100 shown in the perspective, top-down, bottom-up, profile, profile, and cross-sectional views of FIGS. 1A-1F.

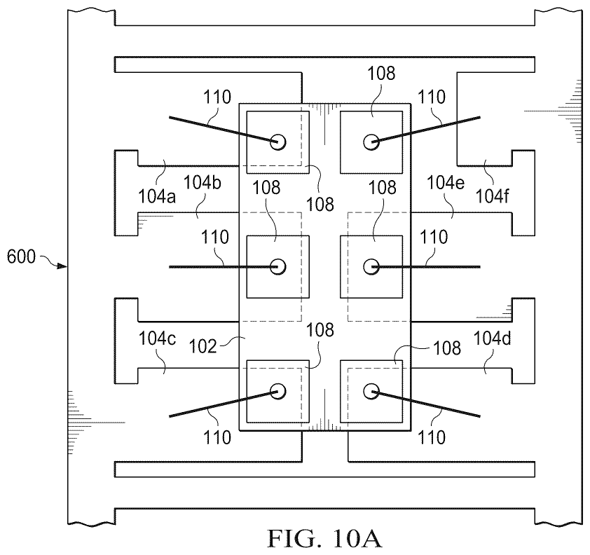

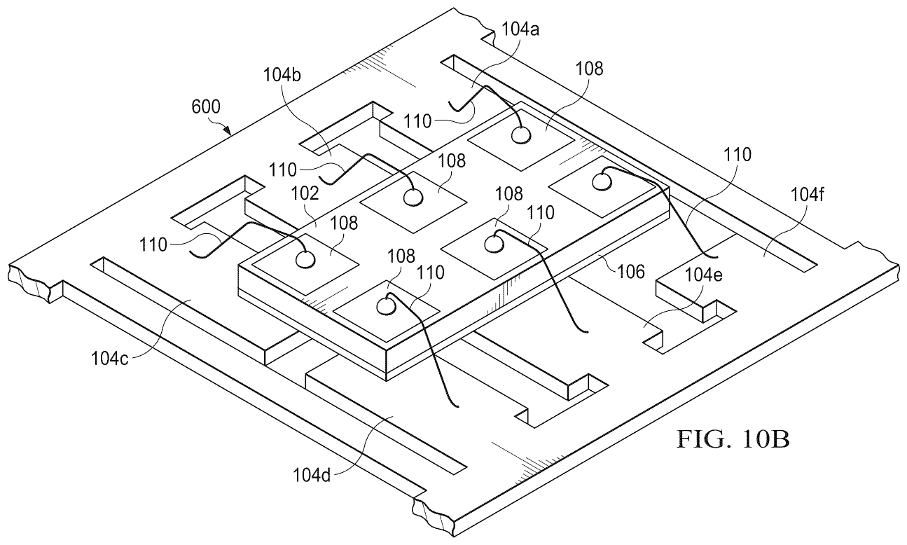

FIGS. 10A and 10B are top-down and perspective views of a portion of a process flow depicting the manufacture of a semiconductor package including distanced conductive terminals, in accordance with various examples. In particular, FIG. 10A shows that a different conductive terminal than the conductive terminal 104e, such as the conductive terminal 104f, may be distanced from the die attach film 106 and the semiconductor die 102, and that the conductive terminal 104e may be useful to provide mechanical support to the semiconductor die 102. FIG. 10B is a perspective view of the structure of FIG. 10A.

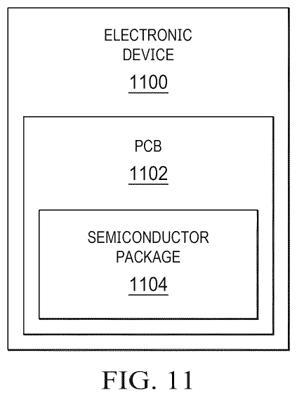

FIG. 11 is a block diagram of an electronic device 1100 including a semiconductor package having distanced conductive terminals, in accordance with various examples. The electronic device 1100 may include a PCB 1102, to which a semiconductor package 1104, such as the semiconductor package 100, may be coupled. Examples of the electronic device 1100 include an automobile, an aircraft, a watercraft, a spacecraft, a video game console, an arcade video game unit, a smartphone, an entertainment device, an appliance, a laptop computer, a desktop computer, a tablet, a notebook, or any other suitable type of electronic device or system.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die having a device side in which circuitry is formed and a non-device side opposite the device side;
a die attach film contacting the non-device side of the semiconductor die;
a first conductive terminal contacting the die attach film, the semiconductor die cantilevered by the first conductive terminal;
a second conductive terminal separated from the die attach film, the first and second conductive terminals configured to operate in different voltage domains;
bond wires coupling the device side of the semiconductor die to the first and second conductive terminals; and
a mold compound contacting the semiconductor die, the die attach film, the first and second conductive terminals, and the bond wires, the mold compound present in between the die attach film and the second conductive terminal, each of the first and second conductive terminals exposed from at least one lateral surface of the mold compound.

2. The semiconductor package of claim 1, wherein a thickness of the mold compound from the die attach film to the second conductive terminal ranges between 10 microns to 1000 microns.

3. The semiconductor package of claim 2, wherein an operating voltage of the semiconductor package ranges from 1 V to 8000 V.

4. The semiconductor package of claim 1, wherein a thickness of the mold compound from the die attach film to the second conductive terminal is adequate to avoid dielectric breakdown when subjected to the range of voltages over which the circuitry is configured to operate.

5. The semiconductor package of claim 1, wherein the second conductive terminal is configured to operate as an anode relative to the semiconductor die, and wherein the semiconductor die is configured to operate as a cathode relative to the second conductive terminal.

6. The semiconductor package of claim 1, wherein the first and second conductive terminals comprise one of copper and silver.

7. The semiconductor package of claim 1, wherein the second conductive terminal is configured to operate in a higher positive voltage range than the first conductive terminal.

8. The semiconductor package of claim 1, further comprising a third conductive terminal exposed from one or more surfaces of the mold compound, the third conductive terminal separated from the die attach film, the mold compound positioned in between the third conductive terminal and the die attach film.

9. A semiconductor package, comprising:
a semiconductor die having a device side in which circuitry is formed and a non-device side opposite the device side;
a die attach film contacting the non-device side of the semiconductor die;
a first conductive terminal contacting the die attach film;
a second conductive terminal separated from the die attach film, the first and second conductive terminals configured to operate in different voltage domains;
bond wires coupling the device side of the semiconductor die to the first and second conductive terminals; and
a mold compound contacting the semiconductor die, the die attach film, the first and second conductive terminals, and the bond wires, a portion of the mold compound present in between the die attach film and the second conductive terminal, the portion of the mold compound having a thickness between the die attach film and the second conductive terminal adequate to avoid dielectric breakdown when subjected to the range of voltages over which the circuitry is configured to operate,
wherein each of the first and second conductive terminals is exposed from at least one lateral surface of the mold compound.

10. The semiconductor package of claim 9, wherein the thickness ranges between 10 microns to 1000 microns.

11. The semiconductor package of claim 10, wherein an operating voltage of the semiconductor package ranges from 1 V to 8000 V.

12. The semiconductor package of claim 9, wherein the first conductive terminal is the only conductive terminal contacting the die attach film, and further comprising a third conductive terminal separated from the die attach film, the mold compound positioned in between the third conductive terminal and the die attach film.

13. The semiconductor package of claim 12, wherein the first conductive terminal contacts more than half of a width of the die attach film as measured along an axis of the first conductive terminal.

14. The semiconductor package of claim 9, wherein the second conductive terminal comprises copper or silver.

15. A semiconductor package, comprising:
a semiconductor die having a device side in which circuitry is formed and a non-device side opposite the device side;
a die attach film contacting the non-device side of the semiconductor die;
a first conductive terminal contacting more than half of a width of the die attach film as measured along an axis of the first conductive terminal;
multiple conductive terminals distanced from the die attach film, the first conductive terminal configured to operate in a separate voltage domain from the multiple conductive terminals; and
a mold compound positioned in between the die attach film and each of the multiple conductive terminals, the mold compound having a thickness between the die attach film and each of the multiple conductive terminals ranging from 10 microns to 1000 microns, the first conductive terminal and each of the multiple conductive terminals exposed from at least one lateral surface of the mold compound.

16. The semiconductor package of claim 15, wherein the thickness of the mold compound is adequate to avoid dielectric breakdown when subjected to the range of voltages over which the circuitry is configured to operate.

17. The semiconductor package of claim 15, wherein an operating voltage of the semiconductor package ranges from 1 V to 8000 V.

18. The semiconductor package of claim 15, wherein at least one of the multiple conductive terminals is configured to operate at a higher positive voltage than the semiconductor die.

19. A method for manufacturing a semiconductor package, comprising:
coupling a die attach film to a non-device side of a semiconductor die, the semiconductor die including a device side opposite the non-device side, the device side having circuitry formed therein;
contacting the die attach film to one or more conductive terminals of a lead frame, the one or more conductive terminals adequately sized to mechanically support the semiconductor die and the die attach film, the lead frame including a conductive terminal separated from the die attach film by a distance ranging from 10 microns to 1000 microns;
coupling bond wires to the device side of the semiconductor die, the one or more conductive terminals, and the conductive terminal;
covering the semiconductor die, the die attach film, and the lead frame with a mold compound, the mold compound positioned between the conductive terminal and the die attach film; and
sawing the mold compound to produce the semiconductor package,
wherein, after the sawing, the conductive terminal and each of the one or more conductive terminals is exposed from at least one lateral surface of the mold compound, the conductive terminal configured to operate in a different voltage domain than the one or more conductive terminals.

20. The method of claim 19, wherein a thickness of the mold compound in between the conductive terminal and the die attach film is adequate to avoid dielectric breakdown when subjected to the range of voltages over which the circuitry is configured to operate.
